(19) United States
(12) Patent Application Publication
(10) Pub. No.: US 2024/0276655 A1
(43) Pub. Date: Aug. 15, 2024

(54) Novel touch screen assembly using improved bonding method

(71) Applicant: Charles Jarod Gharamti, Naples, FL (US)

(72) Inventor: Charles Jarod Gharamti, Naples, FL (US)

(21) Appl. No.: 18/168,437

(22) Filed: Feb. 13, 2023

(51) Int. Cl. H05K 5/00; C09J 7/30

(52) U.S. Cl. CPC H05K 5/0017; C09J 7/30; C09J 2203/326; C09J 2301/124

(57) ABSTRACT

The present invention comprises a novel bonding method. This method is to use double sided adhesive tape to bond the two components of a touch panel for infotainment systems. This method represents a notably different approach to the commonly used industry standard which is to use Liquid Optically Clear Adhesive (Gel). By using this improved gel-free method, the reliability challenges of the current industry design standard are resolved.

### BACKGROUND

Most modern automobiles utilize an infotainment system to control various vehicle settings and view information. The infotainment system is positioned within reach of the driver or passenger, allowing the operator to interact with the system.

These infotainment systems often have a touch screen as the primary input device. The operator uses a touch panel to inform the system what controls should be changed, or what information should be viewed.

This invention relates to the method of constructing the touch panel assembly, and discloses a novel approach to assembly that solves many shortcomings in the currently accepted design standard of assembly.

The traditional, commonly accepted standard design is to use a gel adhesive (liquid optical clear adhesive, or “LOCA”) to bond an outer plastic touch frame to a glass electrical digitizer. Over time, this gel clear adhesive dries and hardens. Often, this defect is called “delamination.” When the gel has dried and delaminated, it no longer transmits touch response to the user, causing many functionality problems. This traditional method of assembly is unreliable and will disable the infotainment system when the gel dries out, causing notable inconvenience and expense to the owner.

### BRIEF SUMMARY OF THE INVENTION

The present invention discloses a method of applying a perimeter of double-sided adhesive tape to assemble the components used for touch panel assemblies. This novel approach resolves the unreliable and commonly used design methods of using clear optical adhesive to bond the two components (touch panel and digitizer)

By using double sided tape to bond the two components together, and removing the clear optical adhesive, reliability and performance are increased.

The novel invention presented herein is not the specifics of the touch panel or digitizer, but rather, the newly discovered and disclosed method of assembly and bonding the two components.

### BRIEF DESCRIPTION OF THE DRAWINGS

FIG. 1 shows the common gel adhesive that is prone to failure. In this example, the gel has hardened to powder and the touch system no longer functions. This is a very common failure that affects nearly all modern vehicles.

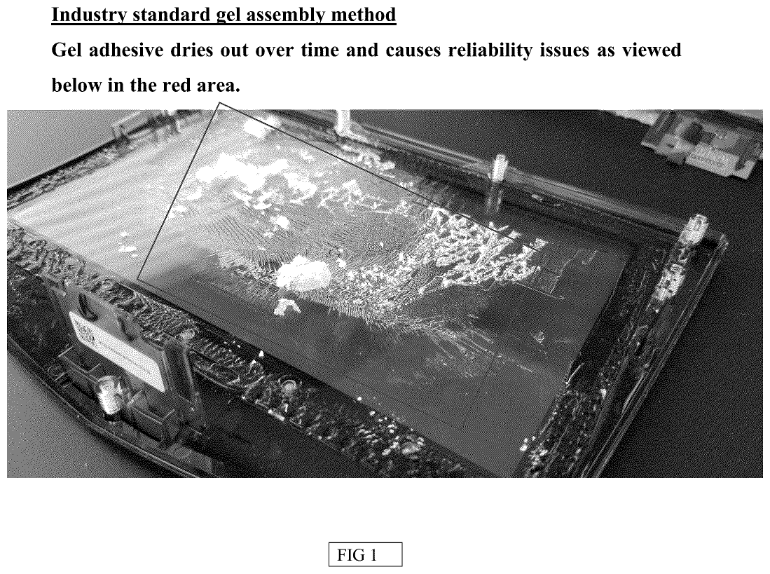

FIG. 2 illustrates the present invention and the novel approach that does not utilize the clear gel adhesive, rather, a perimeter of double-sided tape as shown by the arrow.

FIG. 3 presents the assembly drawing showing the newly invented bonding method.

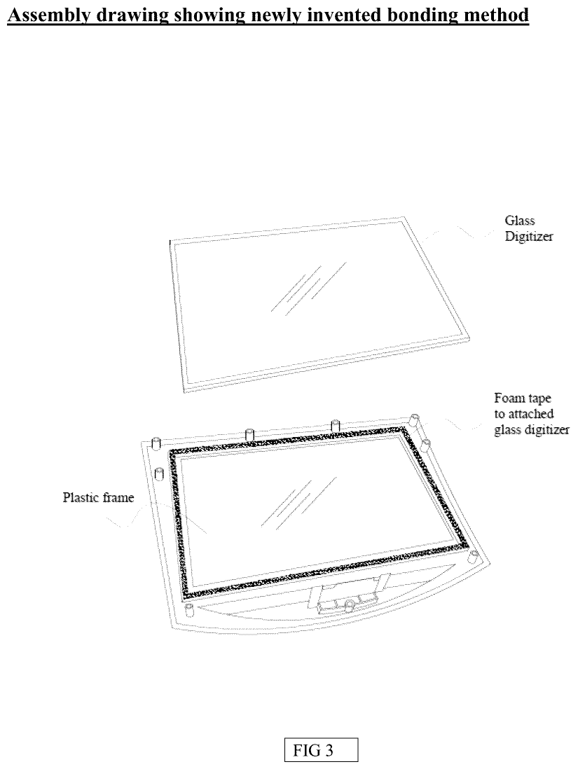

FIG. 4 presents actual images of infotainment systems that use the common adhesive bonding method, and the associated delamination that occurs. The present invention is a novel approach of assembly that resolves these problems.

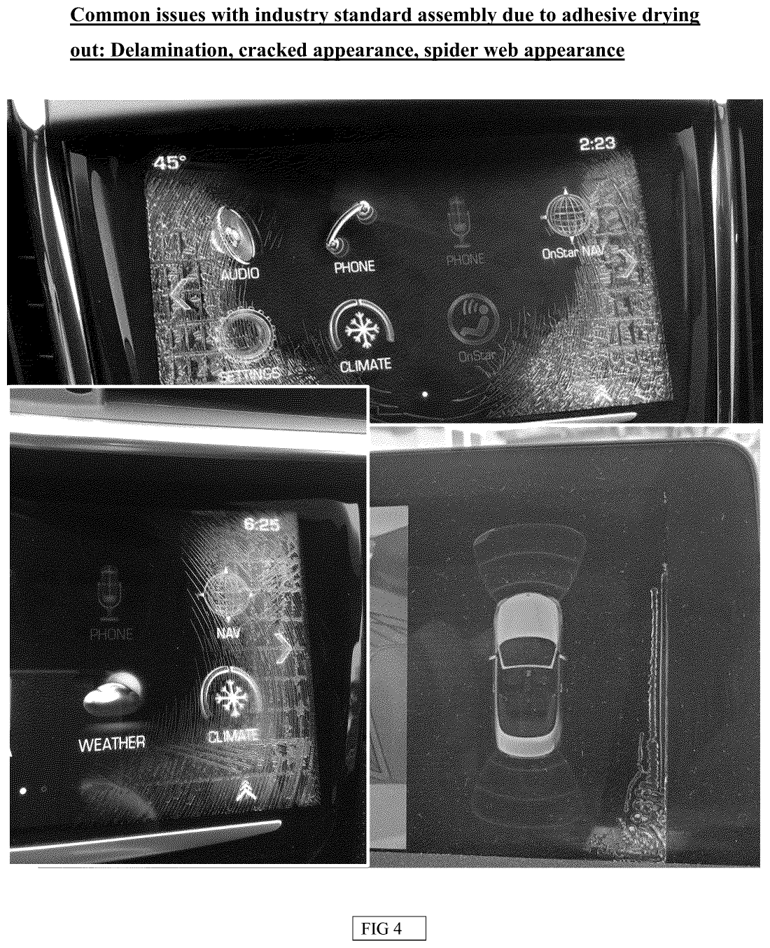

### DETAILED DESCRIPTION AND BEST MODE OF IMPLEMENTATION

A normal touch panel consists of two parts; a glass digitizer and an outer plastic touch frame. The plastic frame is an aesthetic requirement and allows the system to have a stylized appearance while integrating a common rectangular digitizer.\

It is common industry design standard to bond the plastic frame to the glass digitizer with clear optical adhesive.

The present invention is a novel approach and methodology of bonding the two components together, and removes the use of the liquid optical adhesive (gel).

In this invention, a perimeter of double-sided tape secures the plastic frame to the digitizer as the bonding method, instead of the commonly accepted liquid optical adhesive (gel).

### REVIEW OF KNOWN ACTIVE OR PENDING PATENTS

### Active or Pending Patents

1. https://pdfpiw.uspto.gov/.piw?Docid-08405620 (Active patent)

Patent scope/claim interpretation: This patent is for ANY TWO adhesives that bond a touch panel to a device where one of the two has stronger adhesion than the other one. Examples of the adhesives are hot melt and/or light curable.

### Reason why it is not Relevant:

Having a double-sided tape is only ONE adhesive (and even if one were to construe the 2 sides as separate adhesives, they would still be of equal adhesive strength).
2. https://pdfpiw.uspto.gov/.piw?Docid-08576202 (Active patent)

“Peripheral display bonding layer 115 may be a double-sided adhesive tape, an epoxy, or any other means to provide a reliable mechanical bond, and peripheral substrate bonding layer 120 may be an epoxy, double-sided adhesive tape, or any other means to provide a reliable mechanical bond.”

### Reason why it is not Relevant:

Not relevant since patent claims are not directed to bonding touch screen to a housing with double sided tape.
3. http://pdfaiw.uspto.gov/.aiw?Docid=20180366685 (pending)

### Reason why it is not Relevant:

Discloses use of double sided tape to bond components inside a device, but not specifically for bonding touch screen to a housing/frame. Also, it's a different product.

### Expired patents

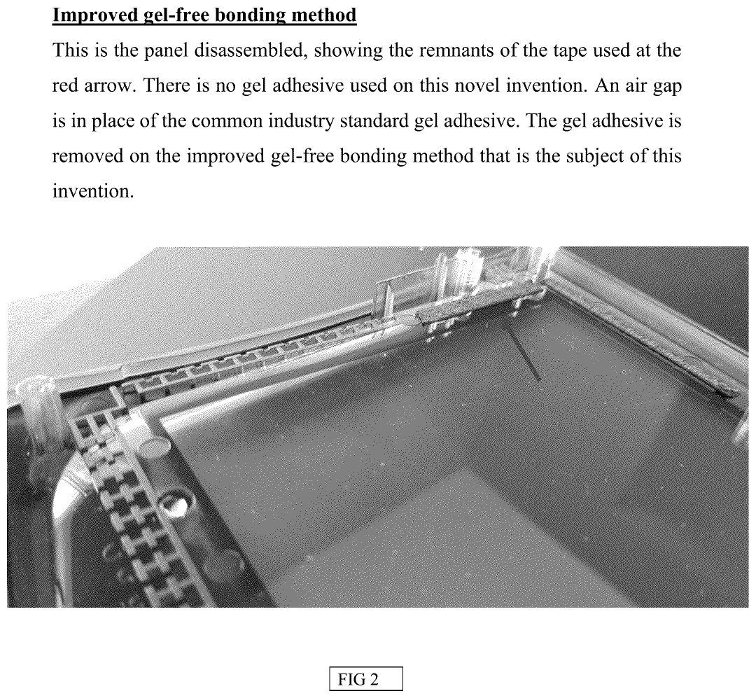

4. https://pdfpiw.uspto.gov/.piw?Docid=06788532 (Uses double sided tape) “Referring to FIG. 2, embodiments of the present invention can include a tempered glass 120 stuck on an upper portion of a front cover 110 using a double sided tape, a LCD (Liquid Crystal Display) panel 123 and a digitizer 126 stacked within the front cover . . . ”
5. https://pdfpiw.uspto.gov/.piw?Docid=04816811 (Uses Gel)
6. https://pdfpiw.uspto.gov/.piw?Docid-06254105 (Uses Gel)
7. https://pdfpiw.uspto.gov/.piw?Docid=05835080 (Uses Gel)

Based on the above, it would be safe to make the product without gel and/or with double-sided tape.

I: A touch panel assembly comprising: A plastic touch frame bonded to a glass digitizer using a perimeter of double sided tape, rather than the conventional design of clear optical adhesive to bond the two pieces. This method is referred to “gel-free.”
